(19) United States
(12) Patent Application Publication
(10) Pub. No.: US 2020/0024180 A1
(43) Pub. Date: Jan. 23, 2020

(54) CONDUCTIVE PASTE FOR SOLAR CELL ELECTRODE AND SOLAR CELL MANUFACTURED USING SAME

(71) Applicant: LS-NIKKO COPPER INC., Ulsan (KR)

(72) Inventors: Min Soo KO, Seoul (KR); In Chul KIM, Yongin (KR); Chung Ho KIM, Namyangju (KR); Hwa Young NOH, Hwaseong (KR); Mun Seok JANG, Seoul (KR); Tae Hyun JUN, Seongnam (KR)

(21) Appl. No.: 16/346,074

(22) PCT Filed: Oct. 18, 2017
(86) PCT No.: PCT/KR2017/011511

§ 371 Date: Jun. 27, 2019

(30) Foreign Application Priority Data
Oct. 31, 2016 (KR) 10-2016-0143687

(51) Int. Cl. C03C 8/18; H01L 31/0224; C03C 4/14

(52) U.S. Cl. CPC C03C 8/18; C03C 2204/00; C03C 4/14; H01L 31/022425

(57) ABSTRACT

The present invention relates to a conductive paste for a solar cell electrode, including a metal powder, a glass frit and an organic vehicle, wherein the metal powder includes a metal powder having a sintering shrinkage rate of 15 to 30%, whereby the light-receiving area of the front electrode of a solar cell formed using the conductive paste including the metal powder having an increased sintering shrinkage rate can be enlarged and short-circuit current (Isc) can be increased, thus increasing the power generation efficiency of the solar cell.

### TECHNICAL FIELD

The present invention relates to a conductive paste for use in the formation of an electrode of a solar cell and a solar cell manufactured using the same.

### BACKGROUND ART

Solar cells are semiconductor devices that convert solar energy into electrical energy, and typically have a p-n junction type, and the basic structure thereof is the same as a diode. FIG. 1 shows the configuration of a general solar cell device. The solar cell device is typically configured using a p-type silicon semiconductor substrate 10 having a thickness of 180 to 250 μm. An n-type impurity layer 20, having a thickness of 0.3 to 0.6 μm, is formed on the light-receiving surface of the silicon semiconductor substrate, and an antireflective film 30 and a front electrode 100 are formed thereon. A rear electrode 50 is also formed on the rear surface of the p-type silicon semiconductor substrate.

The front electrode 100 is formed by applying a conductive paste containing conductive particles of silver as a main component (silver powder), a glass frit, an organic vehicle and an additive, which are mixed therewith, on the antireflective film 30 and then firing it, and the rear electrode 50 is formed by applying an aluminum paste composition comprising an aluminum powder, a glass frit, an organic vehicle and an additive through a screen-printing process or the like, followed by drying and then firing at a temperature of 660° C. (the melting point of aluminum) or higher. Aluminum is diffused into the p-type silicon semiconductor substrate at the time of firing, whereby an Al—Si alloy layer is formed between the rear electrode and the p-type silicon semiconductor substrate, and simultaneously, a p+layer 40 is formed as an impurity layer due to the diffusion of aluminum atoms. The presence of this p+layer prevents the recombination of electrons, and thus a BSF (Back Surface Field) effect, which increases the collection efficiency of the generated carriers, is obtained. A rear silver electrode 60 may be further disposed under the rear aluminum electrode 50.

For the formation of metal electrodes on both surfaces of a silicon wafer, a process of forming an electrode, including printing a paste including a metal powder in a screen-printing manner and then performing drying and firing, is currently mainly used in a crystalline solar cell mass-production line, and the characteristics of the solar cell are achieved through a high-temperature sintering process. In this procedure, particularly for the front electrode, contact resistance formation through melting, expansion and contraction of inorganic materials such as conductive particles and glass frit, as well as burnout of organic materials such as an organic vehicle, and short-circuit current (Isc) formation through ensuring the light-receiving area may result.

Conventionally, since the metal paste printed on the front and rear surfaces of the silicon wafer is a flowable composition, as shown in FIG. 2, changes in line width (finger) and residue (bleeding) occur with increased processing time for printing, drying and firing, and consequently, the light-receiving area is reduced, undesirably deteriorating the efficiency of the solar cell.

Also, in order to increase short-circuit current (Isc), there is a tendency to reduce the line width on a printing mask design to 40 μm, 36 μm, 34 μm and 32 μm, but in the 32 μm line-width design, the reliability of printing quality characteristics is poor and it is difficult to realize an additional line-width reduction.

### DISCLOSURE

### Technical Problem

Accordingly, an objective of the present invention is to provide a conductive paste for a solar cell electrode, in which the sintering shrinkage rate of a metal powder thereof may be increased, thus enlarging the light-receiving area of the front electrode of a solar cell formed using the same and increasing short-circuit current (Isc) to thereby enhance the power generation efficiency of the solar cell.

Another object of the present invention is to provide a conductive paste for a solar cell electrode, in which line resistance may be decreased due to an increase in the sinterability of a metal powder thereof, thus lowering series resistance (Rs) and increasing a fill factor (FF), thereby enhancing the power generation efficiency of the solar cell.

However, the objectives of the present invention are not limited to the foregoing, and other objectives which are not mentioned herein will be able to be clearly understood by those skilled in the art from the following description.

### Technical Solution

The present invention provides a conductive paste for a solar cell electrode, comprising a metal powder, a glass frit and an organic vehicle, in which the metal powder includes a metal powder having a shrinkage rate of 15 to 30%, measured as an area reduction rate after applying, drying and firing the paste including the metal powder, compared to the state before firing.

Also, the metal powder may include at least two selected from the group consisting of a first metal powder having a sintering shrinkage rate of 15 to 20%, a second metal powder having a sintering shrinkage rate of 20 to 25%, and a third metal powder having a sintering shrinkage rate of 25 to 30%.

Also, the metal powder may be configured such that the amount of the metal powder having a relatively high shrinkage rate is greater than the amount of the metal powder having a relatively low shrinkage rate.

In addition, the present invention provides a solar cell, comprising a front electrode provided on a substrate and a rear electrode provided under the substrate, in which the front electrode is manufactured by applying, drying and firing the conductive paste described above.

### ADVANTAGEOUS EFFECTS

According to the present invention, a conductive paste includes a metal powder having an increased sintering shrinkage rate, and thus the light-receiving area of the front electrode of a solar cell formed using the same can be enlarged and short-circuit current (Isc) can be increased, thereby enhancing the power generation efficiency of the solar cell.

Also, according to the present invention, line resistance can be decreased due to an increase in the sinterability of the metal powder of the conductive paste, thus lowering series resistance (Rs) and increasing a fill factor (FF), thereby enhancing the power generation efficiency of the solar cell.

### DESCRIPTION OF DRAWINGS

FIG. 1 shows a schematic cross-sectional view of a typical solar cell device; and

FIG. 2 shows changes in line width and residue during processing upon formation of a conventional solar cell electrode.

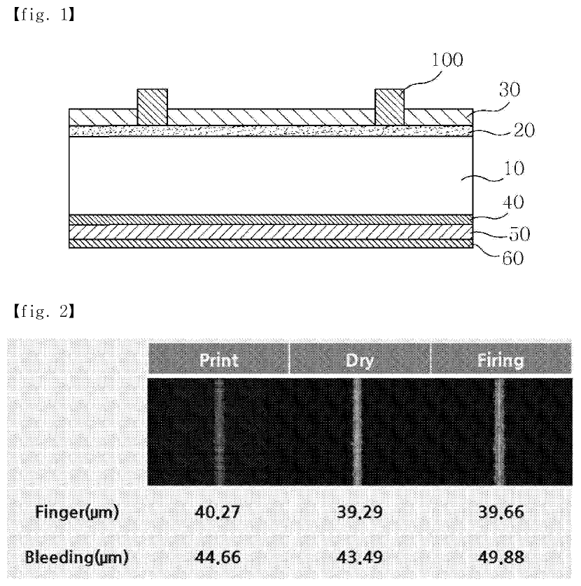

### MODE FOR INVENTION

In the following description of the present invention, the terms used herein are merely intended to describe specific embodiments and are not to be construed as limiting the scope of the present invention, which is defined by the appended claims. Unless otherwise defined, all technical or scientific terms used herein have the same meanings as those typically understood by persons having ordinary knowledge in the art to which the present invention belongs.

Unless otherwise stated, the terms “comprise”, “comprises” and “comprising” are used to designate the presence of an object, a step or groups of objects and steps described to in the specification and claims, and should be understood as not excluding the presence or additional possibility of inclusion of any other objects, steps or groups of objects or steps.

Unless otherwise noted, various embodiments of the present invention may be combined with other embodiments. In particular, any feature that is said to be preferable or favorable may be combined with any other features said to be preferable or favorable. Hereinafter, a description will be given of embodiments of the present invention and effects thereof with reference to the appended drawings.

An embodiment of the present invention pertains to a paste suitable for use in the formation of a solar cell electrode, particularly a conductive paste including a metal powder having an increased sintering shrinkage rate. More particularly, the conductive paste according to the present invention includes a metal powder, a glass frit, an organic vehicle and an additive.

The conductive paste according to the present invention includes a metal powder having an increased sintering shrinkage rate, thus enlarging the light-receiving area of the front electrode of a solar cell formed using the same and increasing short-circuit current (Isc) to thereby enhance the power generation efficiency of the solar cell.

The metal powder may include a silver (Ag) powder, a copper (Cu) powder, a nickel (Ni) powder, and an aluminum (Al) powder, and a silver powder is mainly used for the front electrode and an aluminum powder is mainly used for the rear electrode.

As the metal powder according to an embodiment of the present invention, a metal powder having a shrinkage rate (%) of 15 to 30% may be used. The shrinkage rate may be measured as an area reduction rate after applying, drying and firing the paste including the metal powder and the binder resin, compared to the state before firing. If the shrinkage rate of the metal powder is less than 15%, the line width may become wide, undesirably decreasing short-circuit current (Isc). On the other hand, if the shrinkage rate to thereof exceeds 30%, contact resistance may increase due to excessive firing, which is undesirable. Preferably, a metal powder having a shrinkage rate of 20 to 30%, and more preferably, a metal powder having a shrinkage rate of 25 to 30%, is used.

As the metal powder according to another embodiment of the present invention, a first metal powder having a shrinkage rate of 15 to 20% may be used alone, a second metal powder having a shrinkage rate of 20 to 25% may be used alone, or a third metal powder having a shrinkage rate of 25 to 30% may be used alone. Compared to the case in which the first metal powder is used alone, the use of the second metal powder alone is preferable, and compared to the case in which the second metal powder is used alone, the use of the third metal powder alone is further preferable.

As the metal powder according to still another embodiment of the present invention, a mixture of at least two metal powders having different shrinkage rates may be used. For example, a mixture of the first metal powder and the second metal powder may be used, a mixture of the second metal powder and the third metal powder may be used, or a mixture of the third metal powder and the first metal powder may be used. When a mixture of two metal powders having different shrinkage rates is used, the mixing ratio thereof is not limited, but it is preferred that the amount of the metal powder having a relatively high shrinkage rate be greater than the amount of the metal powder having a relatively low shrinkage rate. Preferably, the second metal powder and the third metal powder are mixed, the amount of the third metal powder that is mixed being 50% or more based on the total amount of the metal powder.

Alternatively, a mixture comprising all of the first metal powder, the second metal powder and the third metal powder may be used. As such, these powders are mixed such that the amount of the third metal powder is the greatest and the amount of the first metal powder is the smallest.

A silver powder having a high shrinkage rate of 15 to 30% may be prepared in a wet reduction manner in which silver particles are precipitated by reacting silver nitrate, ammonia, an organic acid alkali metal salt and a reducing agent.

The amount of the metal powder is 40 to 95 wt % based on the total weight of the conductive paste composition, taking into consideration the thickness and line resistance of an electrode formed upon printing. Preferably, the amount thereof is 60 to 90 wt %.

When a silver powder is contained in the conductive paste in order to form the front electrode for a solar cell, the silver powder is preferably a pure silver powder, and other examples thereof may include a silver-coated complex powder having a silver layer on at least a surface thereof, an alloy composed mainly of silver, etc. Also, the silver may be used in combination with another metal powder. For example, aluminum, gold, palladium, copper, nickel, and the like may be used.

The average particle diameter (D50) of the metal powder may range from 0.5 to 5 μm, and preferably 1 to 3 μm considering ease of formation of a paste and density upon firing, and the shape thereof may be at least one of a spherical shape, an acicular shape, a planar shape, and an indeterminate shape. The silver powder may be used in a mixture of two or more powders having different average particle diameters, particle size distributions and shapes.

The composition, particle diameter and shape of the glass frit are not particularly limited. Not only a lead-containing glass frit but also a lead-free glass frit may be used. As the components and amounts of the glass frit, 5 to 29 mol % of PbO, 20 to 34 mol % of TeO₂, 3 to 20 mol % of Bi₂O₃, 20 mol % or less of SiO₂, and 10 mol % or less of B₂O₃ are preferably used on an oxide basis, and an alkali metal (Li, Na, K, etc.) and an alkaline earth metal (Ca, Mg, etc.) may be contained in an amount of 10 to 20 mol %. When these components are combined in the above amounts, an increase in the line width of the electrode is prevented and superior contact resistance is ensured at high sheet resistance, resulting in superior short-circuit current characteristics.

Also, the average particle diameter of the glass frit is not particularly limited, but may fall in the range of 0.5 to 10 μm, and the glass frit may be used by mixing a variety of particles having different average particle diameters. Preferably, at least one glass frit has an average particle diameter (D50) of 2 μm to 10 μm. Thereby, reactivity upon firing becomes excellent, and in particular, damage to an n layer at a high temperature may be minimized, adhesion may be enhanced, and superior open voltage (Voc) may result. Moreover, an increase in the line width of the electrode upon firing may be reduced.

The amount of the glass frit is preferably 1 to 10 wt % based on the total weight of the conductive paste composition. If the amount thereof is less than 1 wt %, incomplete firing may occur, and thus electrical resistivity may increase, which is undesirable. On the other hand, if the amount thereof exceeds 10 wt %, the glass content in the fired body of the silver powder may become too large, and thus electrical resistivity may increase, which is undesirable.

The organic vehicle is not particularly limited, but may include an organic binder, a solvent, and the like. The solvent may sometimes be omitted. The amount of the organic vehicle is not particularly limited, but is preferably 1 to 30 wt % based on the total weight of the conductive paste composition.

The organic vehicle is used to maintain the uniformly mixed state of the metal powder and the glass frit. For example, when conductive paste is applied onto a substrate through screen printing, the conductive paste is homogenized, thus suppressing the blur and flow of the printed pattern, and moreover, properties that facilitate discharge of the conductive paste from the screen plate and separation of the plate are obtained.

The organic binder contained in the organic vehicle is not particularly limited, but examples thereof may include a cellulose ester compound such as cellulose acetate, cellulose acetate butyrate and the like, a cellulose ether compound such as ethyl cellulose, methyl cellulose, hydroxypropyl cellulose, hydroxyethyl cellulose, hydroxypropylmethyl cellulose, hydroxyethylmethyl cellulose and the like, an acrylic compound such as polyacrylamide, polymethacrylate, polymethylmethacrylate, polyethylmethacrylate and the like, and a vinyl compound such as polyvinyl butyral, polyvinyl acetate, polyvinyl alcohol, and the like. At least one of these organic binders may be selected and used.

As the solvent used for the dilution of the composition, at least one selected from among alpha-terpineol, Texanol, dioctyl phthalate, dibutyl phthalate, cyclohexane, hexane, toluene, benzyl alcohol, dioxane, diethylene glycol, ethylene glycol monobutyl ether, ethylene glycol monobutyl ether acetate, diethylene glycol monobutyl ether, diethylene glycol monobutyl ether acetate, and the like may be used.

The conductive paste composition according to the present invention may further include, as necessary, a typically known additive, for example, a dispersant, a plasticizer, a viscosity modifier, a surfactant, an oxidizing agent, a metal oxide, a metal organic compound and the like.

In addition, the present invention pertains to a method of forming an electrode for a solar cell, in which the conductive paste is applied on a substrate, dried and fired, and to a solar cell electrode manufactured by the method. Here, a substrate, a printing process, a drying process and a firing process useful in conventional methods for manufacturing solar cells may be applied, with the exception that the conductive paste including the silver powder having the properties above is used in the method of forming a solar cell electrode according to the present invention. For example, the substrate may be a silicon wafer.

When an electrode is formed using the conductive paste according to the present invention, a sintering shrinkage rate may be increased even by the use of a printing mask having the same line width, thus enlarging the light-receiving area of the solar cell and increasing short-circuit current (Isc).

Also, line resistance is decreased due to an increase in the sinterability of the metal powder of the conductive paste composition according to the present invention, thus lowering series resistance (Rs) and increasing a fill factor (FF), thereby enhancing the power generation efficiency of the solar cell.

Moreover, the conductive paste according to the present invention may be applied to crystalline solar cell (P-type, N-type), PESC (Passivated Emitter Solar Cell), PERC (Passivated Emitter and Rear Cell), and PERL (Passivated Emitter Real Locally Diffused) structures, and also to modified printing processes such as double printing, dual printing, etc.

### Examples and Comparative Examples

A conductive paste was prepared in a manner in which 0.4 g of ethyl cellulose, 2.3 g of Texanol, 2.0 g of DBA, 1.8 g of DB, 0.3 g of amide wax, 0.2 g of DPGDB, 2.0 g of a glass frit and 1.5 g of a dispersant were placed in a mixer, dispersed using a three-roll mill, mixed with a silver powder, further dispersed using a three-roll mill, and then defoamed under reduced pressure. The properties of the silver powder that was used are shown in Table 1 below.

TABLE 1

| Classification | D50 (μm) | Shrinkage rate (%) |
|---|---|---|
| Silver powder A | 2.1 | 15~20% |
| Silver powder B | 2.18 | 20~25% |
| Silver powder C | 2.06 | 25~30% |
| Silver powder D | 2.5 | 10~15% |
| Silver powder E | 1.7 | 30~35% |

TABLE 2

| | Silver | Silver | Silver | Silver | Silver |
|---|---|---|---|---|---|
| No. | powder A | powder B | powder C | powder D | powder E |
| Example 1 | 100% | | | | |
| Example 2 | | 100% | | | |
| Example 3 | | | 100% | | |
| Example 4 | 40% | 60% | | | |
| Example 5 | | 40% | 60% | | |
| Example 6 | | 60% | 40% | | |
| Example 7 | 40% | | 60% | | |
| Example 8 | 20% | 30% | 50% | | |
| Example 9 | 50% | 30% | 20% | | |
| Comparative | | | | 100% | |
| Example 1 | | | | | |
| Comparative | | | | | 100% |
| Example 2 | | | | | |
| Comparative | | | | 50% | 50% |
| Example 3 | | | | | |

### Test Examples

(1) Measurement of Sintering Shrinkage Rate

1 g of the silver powder of each of Examples and Comparative Examples and 0.15 g of a 10% ethyl cellulose (90% DBA) solution were mixed, and the resultant mixture was applied at a thickness of 200 μm and dried in a convection oven at 80° C. for 3 hr. The dried test sample was cut to a size of 1 mm×1 mm and fired in a belt-type IR firing furnace (CF-series, made by Despatch) for a solar cell at a rate of 250 rpm and an actual peak temperature of 780° C., after which the width and length after shrinking were measured and thus the area reduction rate was determined to be a shrinkage rate.

(2) Measurement of Conversion Efficiency and Resistance

The conductive paste prepared above was pattern-printed on the front surface of a wafer through a screen-printing process using a 40 μm mesh and dried at 200 to 350° C. for 20 sec to 30 sec using a belt-type drying furnace. Thereafter, an aluminum paste was printed on the rear surface of the wafer and dried in the same manner as above. The cell thus formed was fired at 500 to 900° C. for 20 to 30 sec using a belt-type firing furnace, thereby manufacturing a solar cell.

The solar cell thus manufactured was measured for conversion efficiency (Eff), short-circuit current (Isc), open voltage (Voc), fill factor (FF), line resistance (Rline) and series resistance (Rs) using a solar cell efficiency measurement device (cetisPV-Celltest 3, made by Halm). The results are shown in Table 3 below.

The conductive paste of each of Examples 1 to 3 was pattern-printed through a screen-printing process using a 360-16 mesh having therein openings 32 μm in size, and dried and fired in the same manner as above, thus manufacturing a solar cell, which was then measured for conversion efficiency (Eff), short-circuit current (Isc), open voltage (Voc), fill factor (FF), line resistance (Rline) and series resistance (Rs) in the same manner as above. The results are shown in Table 4 below.

TABLE 3

| | Isc | Voc | Eff | FF | Rs | Rline-1 | Rline-2 |
|---|---|---|---|---|---|---|---|
| | (A) | (V) | (%) | (%) | (mΩ) | (Ω) | (Ω) |
| Example 1 | 9.437 | 0.6394 | 19.610 | 77.724 | 2.03 | 40.17 | 40.09 |
| Example 2 | 9.441 | 0.6393 | 19.746 | 78.245 | 1.826 | 38.31 | 36.75 |
| Example 3 | 9.444 | 0.6414 | 19.804 | 78.187 | 1.853 | 38.57 | 35.70 |
| Example 4 | 9.4268 | 0.6399 | 19.706 | 78.127 | 1.94 | 42.11 | 39.51 |
| Example 5 | 9.472 | 0.6402 | 19.812 | 78.14 | 1.75 | 38.4 | 38.4 |
| Example 6 | 9.4279 | 0.6397 | 19.736 | 78.267 | 1.79 | 39.4 | 42.1 |
| Example 7 | 9.438 | 0.64 | 19.806 | 78.455 | 1.8 | 42.9 | 39.7 |
| Example 8 | 9.4285 | 0.6400 | 19.727 | 78.188 | 1.83 | 39.37 | 39.02 |
| Example 9 | 9.438 | 0.6399 | 19.760 | 78.25 | 1.81 | 39.6 | 37.9 |
| Comparative | 9.3941 | 0.6383 | 19.631 | 78.297 | 1.77 | 41.12 | 40.22 |
| Example 1 | | | | | | | |
| Comparative | 9.476 | 0.6385 | 19.504 | 77.09 | 2.19 | 38.00 | 36.22 |
| Example 2 | | | | | | | |
| Comparative | 9.4119 | 0.6383 | 19.708 | 78.453 | 1.70 | 38.95 | 38.44 |
| Example 3 | | | | | | | |

TABLE 4

| | Isc | Voc | Eff | FF | Rs | Rline-1 | Rline-2 |
|---|---|---|---|---|---|---|---|
| | (A) | (V) | (%) | (%) | (mΩ) | (Ω) | (Ω) |
| Example 1 | 9.401 | 0.6382 | 19.707 | 78.556 | 1.637 | 33.22 | 33.37 |
| Example 2 | 9.416 | 0.6383 | 19.761 | 78.635 | 1.625 | 33.00 | 33.11 |
| Example 3 | 9.429 | 0.6387 | 19.807 | 78.651 | 1.568 | 31.86 | 32.44 |

Given that the efficiency of a solar cell is measured in 0.2% increments and an increase in efficiency of 0.2% is very meaningful, as shown in Table 3, the solar cell including the electrode made of the conductive paste including the metal powder having a shrinkage rate (%) of 15 to 30% according to the present invention was high in short-circuit current compared to Comparative Example 1 including the metal powder having a shrinkage rate of 15% or less, and was low in series resistance compared to Comparative Example 2 including the metal powder having a shrinkage rate of 30% or more, thus exhibiting high conversion efficiency, resulting in increased power generation efficiency of the solar cell.

Also, short-circuit current and conversion efficiency were higher in Examples 4 to 9 using the mixtures of two or more metal powders having different shrinkage rates than in Examples 1 to 3 using the metal powder alone, and moreover, short-circuit current and conversion efficiency were higher in Examples 5 and 8, in which the metal powder having a high shrinkage rate was mixed in a larger amount, than in Examples 6 and 9, in which the metal powder having a low shrinkage rate was mixed in a larger amount, thereby exhibiting superior power generation efficiency of a solar cell.

Furthermore, as shown in Table 4, sufficient short-circuit current was confirmed to be ensured even at a wide line width of 40 μm compared to the case in which a fine line width of 32 μm was formed using the conductive paste according to the present invention.

The features, structures, effects and the like illustrated in the individual exemplary embodiments above may be combined or modified with other exemplary embodiments by those skilled in the art. Therefore, content related to such combinations or modifications should be understood to fall within the scope of the present invention.

1. A conductive paste for a solar cell electrode, comprising a metal powder, a glass frit, and an organic vehicle,
wherein the metal powder includes a metal powder having a shrinkage rate of 15 to 30%, measured as an area reduction rate after applying, drying and firing the paste including the metal powder, compared to before firing.

2. The conductive paste of claim 1, wherein the metal powder includes a first metal powder having a sintering shrinkage rate of 15 to 20%.

3. The conductive paste of claim 1, wherein the metal powder includes a second metal powder having a sintering shrinkage rate of 20 to 25%.

4. The conductive paste of claim 1, wherein the metal powder includes a third metal powder having a sintering shrinkage rate of 25 to 30%.

5. The conductive paste of claim 1, wherein the metal powder includes at least two metal powders selected from the group consisting of a first metal powder having a sintering shrinkage rate of 15 to 20%, a second metal powder having a sintering shrinkage rate of 20 to 25%, and a third metal powder having a sintering shrinkage rate of 25 to 30%.

6. The conductive paste of claim 5, wherein the metal powder is configured such that an amount of the metal powder having a relatively high shrinkage rate is greater than an amount of the metal powder having a relatively low shrinkage rate.

7. The conductive paste of claim 1, wherein the metal powder has an average particle diameter (D50) of 0.5 to 5 μm.

8. A solar cell, comprising a front electrode provided on a substrate and a rear electrode provided under the substrate,
wherein the front electrode is manufactured by applying, drying and firing the conductive paste of claim 1.
